(19) United States
(12) Patent Application Publication
(10) Pub. No.: US 2002/0116420 A1
(43) Pub. Date: Aug. 22, 2002

(54) Method and apparatus for displaying and viewing electronic information

(76) Inventors: Scott Gerald Allam, Edgewater, MD (US); Mark Todd Broussard, Aurora, IL (US); Carole Grace Saylor, Dunkirk, MD (US); Gary Charles Staas, Scotts Valley, CA (US)

Correspondence Address: WELSH & KATZ, LTD, 120 S RIVERSIDE PLAZA, 22ND FLOOR, CHICAGO, IL, 60606, US

(21) Appl. No.: 09/738,598

(22) Filed: Dec. 15, 2000

Related U.S. Application Data
(60) Provisional application No. 60/236,236, filed on Sep. 28, 2000.

(51) Int. Cl. H05K 1/00; G06F 17/21

(52) U.S. Cl. 707/526; 174/250; 707/512

(57) ABSTRACT

A method and system for displaying and viewing electronic information using a computerized interface is disclosed. The invention creates innovative underlying associations between graphic images of physical pages and extracted electronic information from the graphic images to display electronic information in a manner that mimics reading physical pages. The invention utilizes annotations to bound extracted electronic information and stores annotations in a structure tree of an information manager. The invention also provides a method for advancing through these underlying associations by using an enhanced interactive window. The user selects electronic information from an initial display and advances by “clicking” in the enhanced interactive window. Further, the user can add notes, create summary documents, and utilize a dictionary. The invention also provides a system that incorporates this method and these underlying associations. Such a system may reside on a desktop computer, laptop, or personal digital assistant and may be an application sitting on top of an underlying operating system or be incorporated in the operating system itself.

### CROSS REFERENCE TO RELATED APPLICATIONS

The present application claims the benefit of U.S. Provisional Patent Application Ser. No. 60/236,236 entitled METHOD AND APPARATUS FOR DISPLAYING AND VIEWING ELECTRONIC INFORMATION, filed on Sep. 28, 2000.

### FIELD OF THE INVENTION

The present invention is directed to methods and apparatus for displaying and viewing electronic information, for uses such as electronic books and electronic coursebooks, as well as more generalized viewing and displaying of electronic text.

### BACKGROUND OF THE INVENTION

Recently, there has been an explosion in the market for electronic texts. Viewing textual information in electronic form while preserving physical aspects of the electronic text, however, is a challenge. Electronic documents, nevertheless, have a number of advantages over paper documents including their ease of transmission, their compact storage, and their ability to be edited and/or electronically manipulated. An electronic document typically has information content (such as text, graphics, and images), as in a physical document, and formatting information that directs how the content is to be displayed. Further, electronic documents now include sound, full motion video, and other multimedia content which are not available in a physical document. Because of these advantages, the demand for electronic texts has grown.

A type of electronic document which has gained widespread acceptance among authors, distributors, and publishers is Portable Document Format (PDF) developed by Adobe Systems, Inc. of San Jose, Calif. PDF is a page description file format which describes the visual appearance of a document's physical page, including fonts and special characters, images, and layout. PDF keeps the design of a page fixed and communicates the physical structure through visual cues such as fonts and font size, indentation, and placement on a page or screen. Further, PDF allows for sophisticated typography, non-Roman alphabets, and mathematical and chemical equations. Thus, PDF files are a preferred file format for distributing electronic text for the intent of printing and are widely used in the publishing industry.

One problem with the electronic viewing of PDF documents and other page description or document file formats is that pages in files are dependent upon the concept of a paper page. Since pages in prior art page description or document file formats retain the concept of a physical page, pages are difficult to resize without loss of legibility and may not adapt to screens of different sizes. Because of this limitation, working with and viewing a page is cumbersome. Pages may be best viewed in full-page view, however, when done so, the text is too small to read. For a computer user to view a letter-sized page on a screen and still be able to read the text, the computer user must zoom closer and scroll up and down or left and right to fully understand the information on the representation of the physical page. This makes the task of reading quite awkward.

Electronic documents, and particularly textbooks, often span many pages, more often hundreds of pages. Some prior art page description or document file formats, such as PDF, have illegible text when the page is in full view and a reader may have to zoom closer and subsequently scroll down to read text in different parts of the page. This can make reading of the electronic document difficult. Further, a reader of the electronic textbook may become frustrated, print out a hard copy of the file and discontinue using the electronic text. Having to scroll down to finish reading a column on a page, scrolling up to read another column, and scrolling down to finish reading the second column for each and every page in the electronic text is quite frustrating. Being able to read an electronic textbook without having to scroll down a page is desirable.

Another type of electronic document is one that adheres to Open eBook (OEB) standards that are derived from Extensible Markup Language (XML) and HyperText Markup Language (HTML) markup tags. Open eBook provides for a set of rules that allow for coding of electronic information and for providing an interface so that electronic reader software is able to interpret the electronic information. OEB utilizes XML to create descriptions of text data that can be embedded in the text file itself and provides coding practice requirements for the XML descriptions in order for an electronic document to be OEB compliant. A number of manufacturers have come together to support the OEB standard.

One problem with formatting documents adhering to the OEB standard is that it requires a considerable understanding of text markup. Requiring such understanding has proven to be difficult for many authors and publishers who think in terms of the appearance of the printed page. Another problem with OEB is that conversion of electronic information to the OEB standard is difficult and cumbersome. More significant problems are that OEB has the same limitations that XML and HTML have. That is, OEB does not allow for sophisticated typography, does not allow for control over screen sizes and resolutions, and has limited control over element placement. Further, OEB does not have a provision for complex mathematical or chemical equations. Also, since OEB does not preserve the format of the physical page, a computer user reading an electronic text using the OEB standard may not know how many physical pages he or she has read. Physical information such as the size of the book in pages, the number of pages in a chapter, and other physical properties of a book are lost when a physical book has been converted to the OEB standard.

While PDF and other page description or document file formats may perform better in these areas, as mentioned above, these formats also have restrictions which limit their use for viewing electronic information. By being limited to the definition of a physical page, prior art formats do not allow for textual information to be easily viewed by a computer user. Because of many of these limitations of the prior art products, consumers may prefer physical copies rather than an electronic version.

Improved displaying and viewing systems and methods would be desirable, particularly for electronic documents that present a large amount of electronic information.

Various aspects of the invention are described in more detail in the following Drawings and Detailed Description of the Invention.

### BRIEF DESCRIPTION OF THE DRAWINGS

FIG. 1 is a block diagram illustrating a general overview of an embodiment of the present invention.

FIG. 2 is a system diagram illustrating an example environment for FIG. 1.

FIG. 3 is an illustration of an example “Enhanced Interactive Window,” (used herein as “EIW”) of FIG. 1.

FIG. 4 is an illustration of an example picture and caption for the EIW of FIG. 1.

FIG. 5 is an illustration of a menu used in EIW of FIG. 1.

FIG. 6 is an illustration of bookmarks used to initiate extraction of page elements for use in the EIW of FIG. 1.

FIG. 7 is an illustration of audiovisual clips used in EIW of FIG. 1.

FIG. 8 is an illustration of a link in EIW of FIG. 1.

FIG. 9 is a flow diagram of a structure tree used in the information manager of FIG. 1.

FIG. 10 is an illustration of the relationship between a document page and the EIW of FIG. 1.

FIG. 11 is another illustration of the relationship between a document page and the EIW of FIG. 1.

FIG. 12 is a flow diagram of a method for displaying and viewing electronic information.

FIG. 13 is a flow diagram of the process of following markup annotations.

FIG. 14 is a flow diagram for creating a study guide for FIG. 1.

FIG. 15 is an example of a study guide created by the process of FIG. 14.

FIG. 16 is an illustration of a note tool of FIG. 1.

FIG. 17 is an illustration of a dictionary tool of FIG. 1.

### DETAILED DESCRIPTION OF THE INVENTION

Generally, the present invention is for methods and apparatus for displaying and viewing electronic information. In one aspect, the method comprises displaying a representation of a physical page from an electronic document, extracting information from the representation, and presenting the extracted information in an enhanced interactive window. As used herein, “physical page” is defined as a piece of paper that has top, bottom, and side margins and many physical pages typically make up a book. An illustrative embodiment of the invention is depicted graphically in the drawings and is explained below.

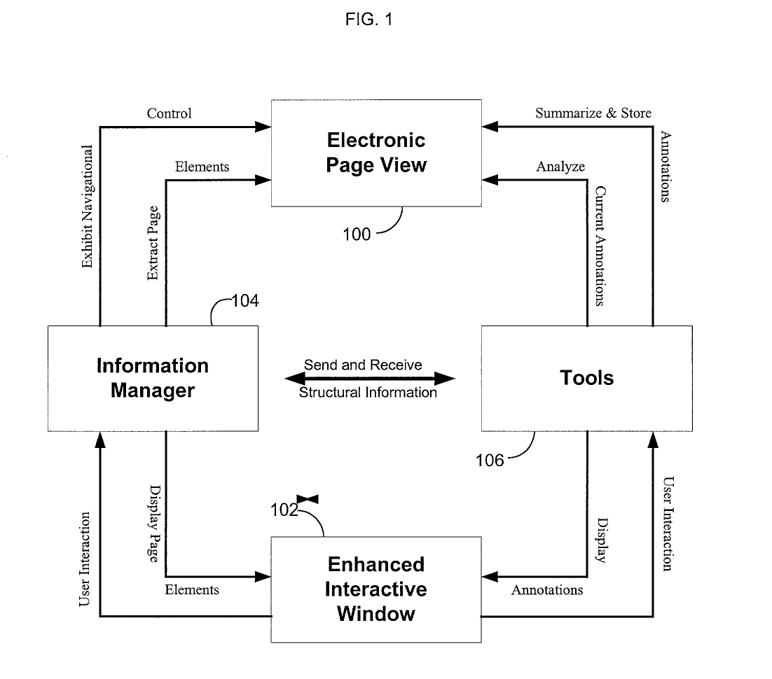

Referring now to the drawings, FIG. 1 diagrammatically illustrates an embodiment of a system for management of electronic information in accordance with the present invention. Briefly, the electronic information management system may be described as comprising an electronic page view 100, an enhanced interactive window (as used herein, “EIW”) 102, an information manager 104, and tools 106. The EIW 102, information manager 104 and tools 106 when used together enhance the readability, navigation and usability of the electronic page view 100. The EIW 102 depicts electronic information from the electronic page view 100 in an easy to read format and provides the user access to the tools 106. Further, the EIW 102 enables the user to exhibit navigational control over the electronic page view 100 by turning pages, zooming to pertinent page elements, hyperlinking to related topics and initiating actions within the electronic page view 100. The information manager 104 organizes information from an electronic document, preferably in a page description or document file format, and maintains a link to the EIW 102 by analyzing relationships between the electronic document and the EIW 102 through a structure tree and word analysis. The tools 106 allow the user to access the information in the information manager 104 and to add user created annotations. The information manager 104 will store, either internally or externally to the electronic document, information which defines the relationship of the user created annotation to the electronic page view 100. Tools include software and hardware applications such as a typed and stylus notes tool, highlighting, file appending, bookmarking, dictionary, and study guide creation. Further, various aspects of the present invention can be implemented in either hardware or software, or both.

I. Illustrative Environment

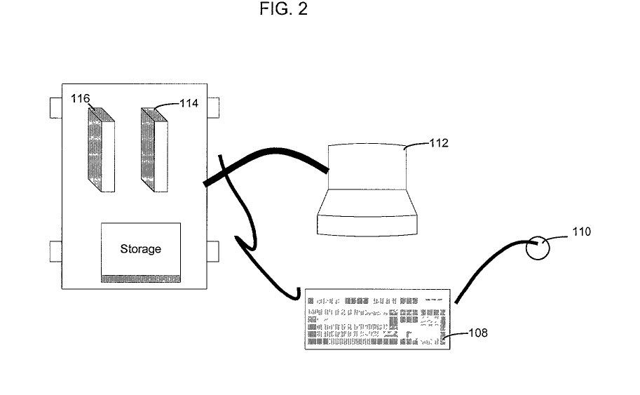

An embodiment of the present invention may be employed and used in conjunction with any computer system, such as a personal desktop computer, a notebook computer, a computer network, a personal digital assistant (PDA), a cellular telephone, or a mobile/wireless assistant. For example, as shown in FIG. 2, a computer system such as a personal desktop computer including a monitor, a keyboard, a mouse, random access memory (RAM) and storage in the form of a hard disk. In addition, the computer may also include a floppy disk, a CD-ROM drive, read-only-memory, and a modem, as are well known in the art. The electronic information management system may also be implemented on computing platforms that emerge in the future, but in the embodiment described below it is implemented on a desktop computer. Specifically, a cellular telephone or a wireless digital assistant may also be an appropriate computing platform for an embodiment of the present invention.

An embodiment of the present invention operates on top of computer operating software currently available on a number of platforms, such as Microsoft Windows™, Apple MacOS™ and Sun Solaris™. The computer system may be running Windows 98, Windows NT, or equivalent, Palm OS, WindowsCE, or equivalent, or an operating system used on Apple or Sun Computers. An embodiment of the present invention is not limited to a particular operating system or computer system to function.

An embodiment of the present invention is provided as software, which may be loaded from floppy disks, from a CD-ROM, over a network, or from any other suitable storage media. The software may be loaded onto the hard disk drive of a computer in a manner that is known to those skilled in the art.

The display may be any display that may be viewed by the computer user. For example, it may be a cathode ray display, or a dual scan display on a notebook computer, or an active matrix display on a notebook computer. The display may optionally be touch sensitive.

The RAM may be any conventional RAM that is known to those skilled in the art. The same is true of the ROM of the computer. The permanent storage may be in the form of conventional hard drives, read-write CD-ROMs, disks, or any other medium that stores data when the computer is not operating. In order to enter data or other information, the user may use a keyboard, either alone or in conjunction with a pointing device, such as a mouse, or a pointer used on a touch sensitive screen. Alternatively, the information may be entered by voice command using any conventional voice command software package.

In addition to a personal computer, this invention may be practiced using a network computer, a “dumb terminal” on a multi-user system, or an Internet or Intranet computer, in which software is resident on the Internet or Intranet, rather than stored on a hard disk on a personal computer. Further, the computer may either operate in a stand-alone mode or over a network.

While the above embodiment describes a single computer, it will be understood that the functionality may be distributed over a plurality of computers. For example, in a distributed architecture, an embodiment of the present invention may be implemented as a Web server.

II. Operation of an Illustrative Embodiment of the Present Invention

A. Enhanced Interactive Window (“EIW”)

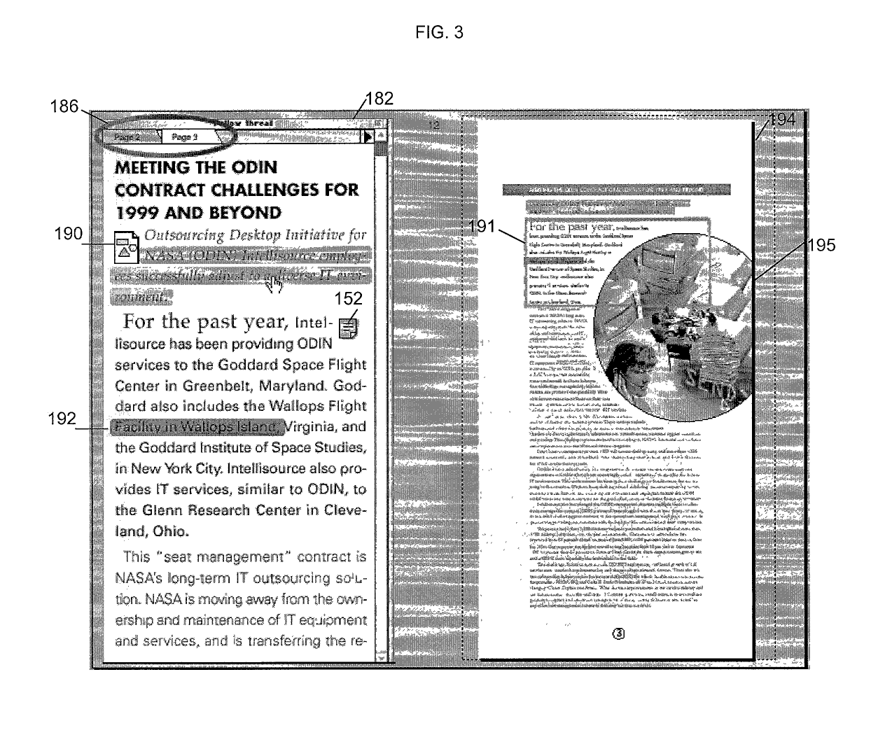

In an illustrative embodiment, the EIW 102 allows for displaying and viewing of electronic information. It contains electronic information from and works in tandem with an electronic document adhering to a page description or document file format, such as the PDF file format. The EIW 102 serves as a control panel for managing information in an electronic document. In FIG. 3, EIW 102 is shown as a graphical user interface and is labeled EIW 182 and electronic page view 100 is shown in graphical form as electronic page view 194. The EIW 182 includes a display area for textual and graphical information, menus and control bars, which are derived from and exhibit navigational control over the electronic page view 194. The text in the display area of the EIW 182 is “free-flowing text”, which means sentences and paragraphs flow without interruption and the line breaks and hyphenation are handled dynamically depending on the font size and column width. Included in the display area of the EIW 182 is an information bar 186 that contains the page number of the physical page being displayed in the electronic page view 194. Although in one embodiment physical document wide orientation is maintained by displaying the page number in EIW 182, the same information may be presented by displaying thumbnail views representing pages in a book, where thumbnail may be an icon or graphic image. Further, physical orientation may also be maintained by listing current page references in an information palette, listing remaining pages for a particular chapter or section being presented in an information palette, and by using graphical representations including a visual slider bar. The visual slider bar may graphically represent a time line with a begin, end, and a current page marker, so that a reader can visually see where the current page is in relation to the book as a whole or portions of the book, such as a chapter.

During customary reading behavior, a reader starts reading at the top of a column and finishes at the bottom. Likewise, information in the EIW 182 begins at the top of the EIW 182 and does not arbitrarily begin in the middle. Using a page down function, prior art products may force the user to begin reading newly presented text in the middle of the window, because there were not enough lines of text to create a whole column's worth. An illustrative embodiment of the present invention overcomes this limitation. Structuring electronic information by adding white space at the bottom of the window when there are not enough lines of text to make a full column, will assure that new information always begins at the top of the EIW 182.

As shown in FIG. 3, the electronic page view 194 has a green box 191 bounding the text in the paragraph. The box 191 is termed a visual reference and is used to show that the text within the box has been extracted and is displayed in the accompanying display area of the EIW 182. As used herein, the box 191 is termed a “markup annotation.” A markup annotation is a box around elements in the electronic page view 194. Although a green box has been used in FIG. 3, the markup annotation may have been another color. Further, the markup annotation may have been emphasized by other types of visual references including highlighting or other emphasizing means to show that the text within the markup annotation is being displayed in an accompanying display area of the EIW 182.

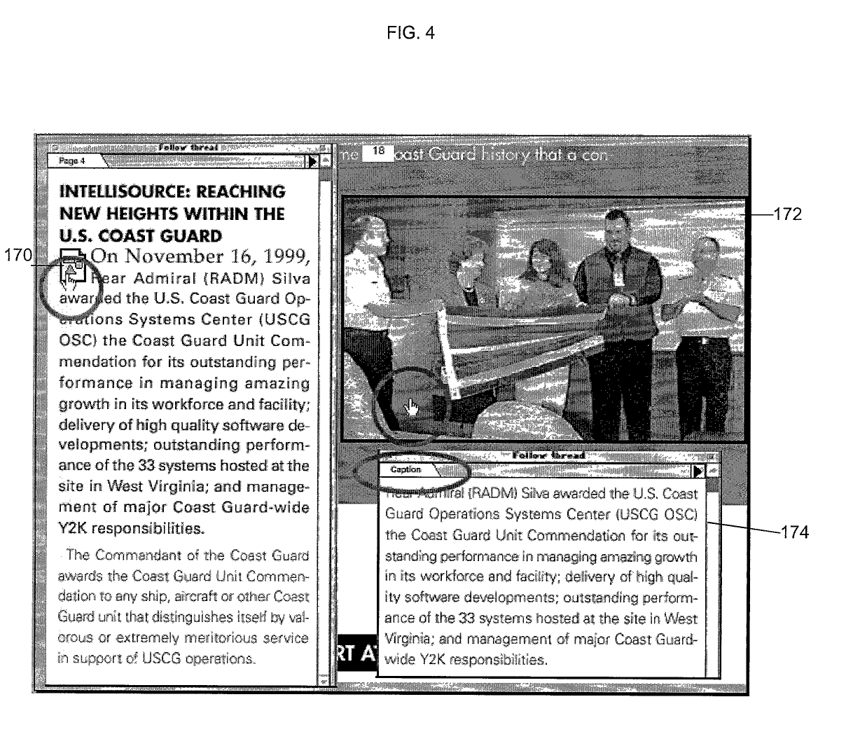

As shown in FIG. 3, text 192 is highlighted which denotes that the text has been marked for future reference and may have associated information, where the associated information is termed a note. FIG. 3 also depicts picture icon 190 that represents the picture 195 on the electronic page view 194. Pictures may be enlarged and have associated captions that the computer user may want to view. Shown in FIG. 4 is an example screen shot depicting this feature. Clicking on picture icon 170 or picture 172 enlarges the picture 172 associated with the icon 170. In one embodiment, the enlarged picture 172 is displayed in a new window. Clicking on picture icon 170 or the enlarged picture 172 again returns the user to a previously viewed setting which was stored prior to enlarging picture 172. Enlarging picture 172 also displays the text for the picture in another enhanced interactive window 174.

Referring back to FIG. 3, in an illustrative embodiment of the present invention, electronic page view 194 is represented by a page in an electronic document adhering to the PDF file format. Although the PDF file format has been used to represent the physical page, the PDF file format is not meant as a limitation. On the contrary, other document file formats which may describe a page may be suitable, such as HTML or a word processing document format. In addition to other document file formats, other electronic representations of physical pages (whether now known or hereafter devised) may be used to represent the physical page for extraction into an EIW 182. For example, the physical page may be represented by a bitmap or a Shockwave™ ActiveX™ image.

In an alternative embodiment, the EIW 182 may be viewed in a separate window and may be managed by a separate control panel. The EIW 182 may be minimized, maximized, manually re-sized and moved by the computer user. Additionally, multiple EIWs are allowed, where each is a separate entity with unique contents and can be maneuvered independently of each other. In yet another alternative embodiment, the electronic page view 194 may also be viewed in a separate window and may be managed by a separate control panel. In any case, the window for the electronic page view may also be minimized, maximized, manually re-sized and moved by the computer user. Further, viewing the separate windows may be accomplished by other means, such as entering a keystroke or “toggling” to change between the views. In yet another embodiment, the electronic page view may be a small icon of a book with small annotations representing the text that is selected. For example, on a small monitor such as used in PDAs, a flashing square on a book icon may represent a selected annotation while the rest of the monitor is used for displaying the extracted text, such as shown in the display area of the EIW 182 of FIG. 3.

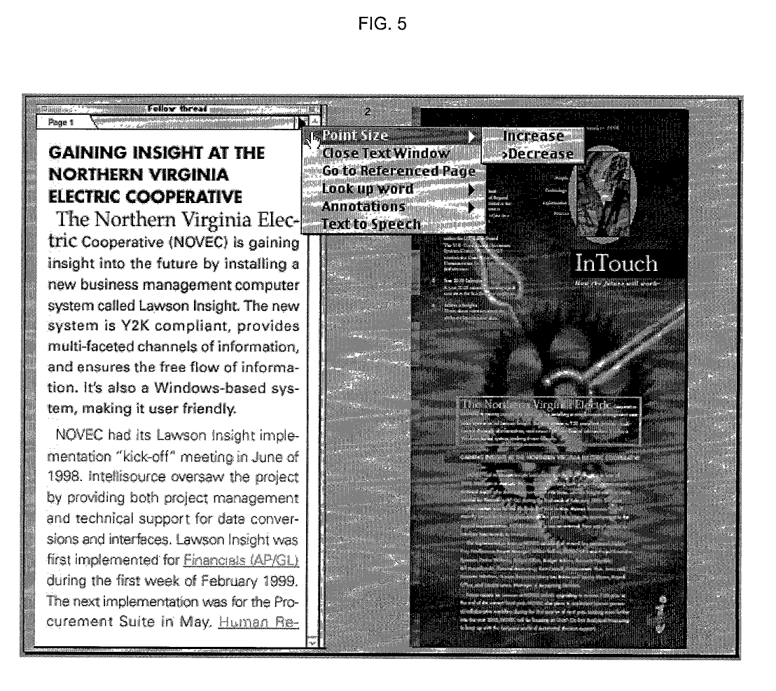

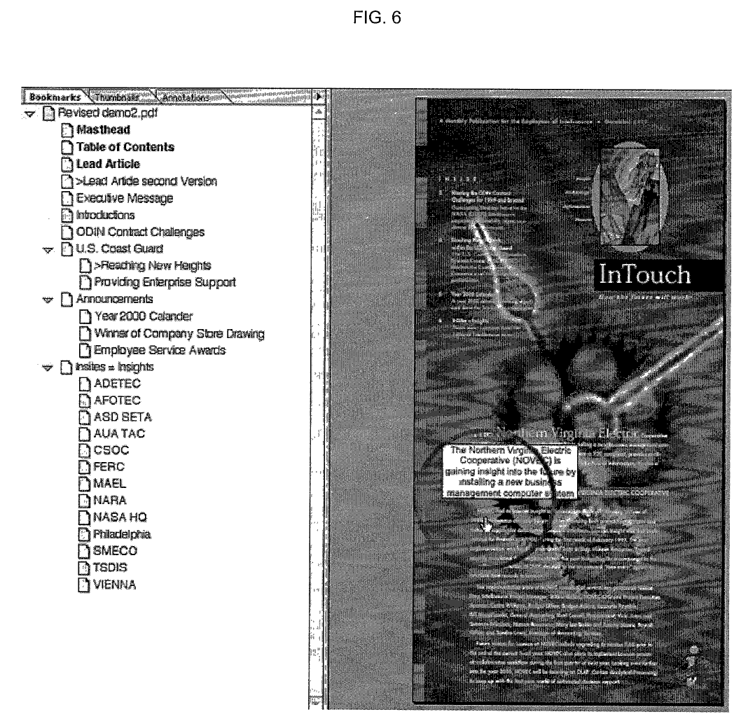

The EIW 182 may also contain icons that represent notes that may be added to the text. Referring back to FIG. 3, there is shown an icon 152 that represents a note. The EIW 182 may also include control buttons (not shown) which may be used to markup the text in the EIW 182. These control buttons and other controls in the EIW provide access to the tools 106. In FIG. 3, text 192 is highlighted using control buttons in the EIW 182. The EIW 182 may also include a control bar 186 which shows page numbers in the boxed portion 191 of the electronic page view 194. Also, the user may increase or decrease the font of the text in the EIW 182. Shown in FIG. 5 is an example screen shot of the menu and submenus used to increase or decrease the font of the text in the EIW 182. The text extraction for use in the EIW 102 may be initiated by bookmarks, which point to chapters, sections, headings, and other structural information in an electronic document. Shown in FIG. 6 is an example screen shot of Adobe™ Acrobat™ bookmarks for an associated PDF electronic document.

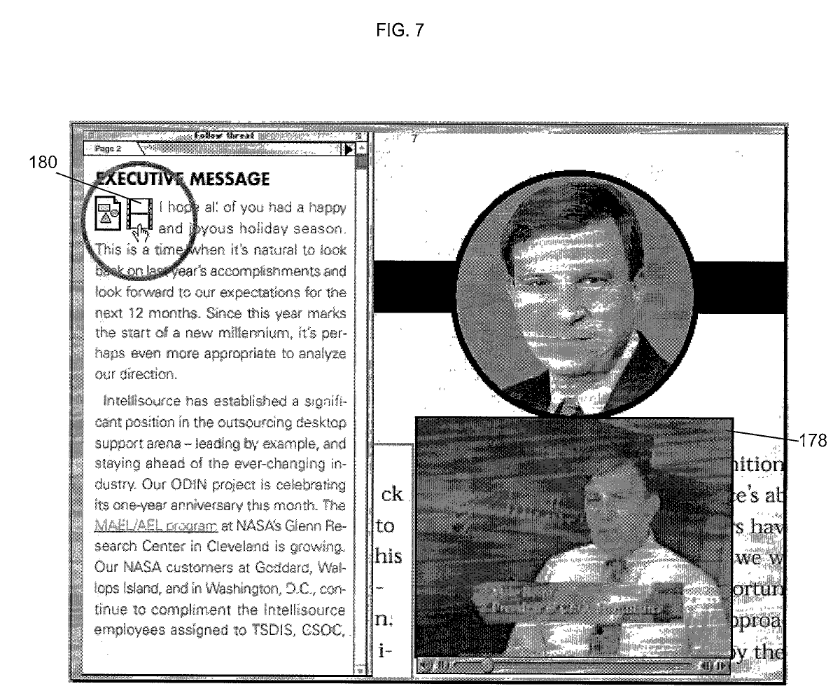

In addition to text, the electronic information displayed in EIW 182 may include icons and hypertext which represents pictures or images, graphs or other statistical information; URLs, file names and file paths for information on the Internet or a networked computer, and sidebars, related sections and other structured elements. The information may also include icons representing and providing access to audio or audiovisual clips. Activating these icons and hyperlinks will perform some action appropriate to their represented element. For example, FIG. 7 shows an embedded audiovisual clip 178 represented in the EIW 182 as film icon 180. When the user selects the film icon 180, for example, by clicking on the film icon 180, a sequence of steps is carried out. These include launching a movie player, which is capable of playing the audiovisual clip, executing a code sequence to perform commands relating to playing the audiovisual clip, opening a file containing the audiovisual clip, and playing the audiovisual clip. As is known in the art, selection of an icon on a graphical user interface may be performed by actions including passing a mouse over the icon and executing keystrokes selecting the icon. Further, the information represented in the EIW 102 may include music, audio compositions, visual clips, and other sensory information as may be developed in the future.

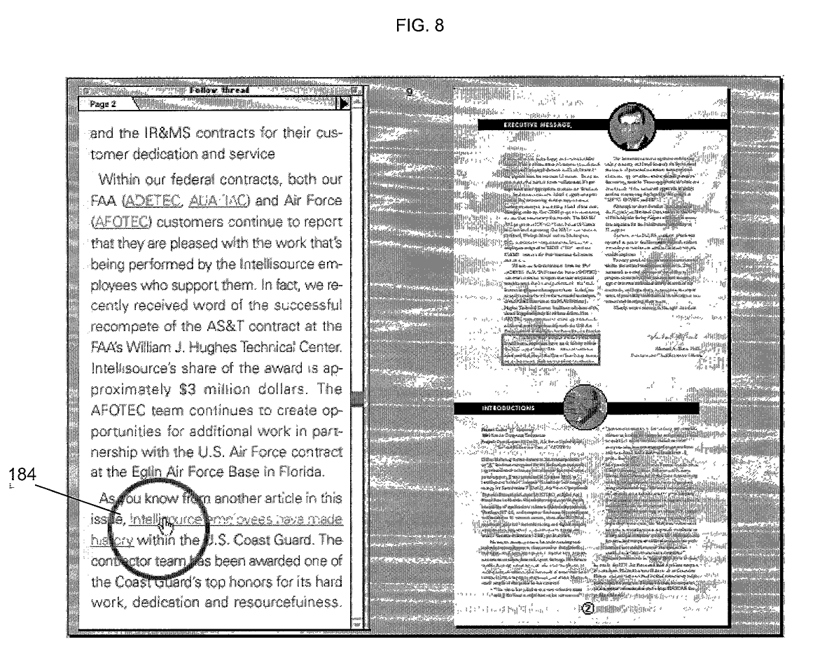

The EIW 102 also allows for inner and outer document links between pages or structural elements of the document. Varying properties, such as color, font, size, etc., associated with the text depicts linking to another document element or structural element. For example, shown in FIG. 8 is a link 184 to another page in or out of the electronic document from the displayed page. When the user selects the link 184, for example, by clicking on the link 184, a sequence of steps is carried out. These include launching a browser which displays the information associated with the link, changing the display of the electronic page view 100, marking the electronic page view 100 with the appropriate markup annotations representing the link, and executing code sequences to perform commands to display information relating to the link. Note that in this example, the link 184 was available in the EIW 102, but the link 184 may also be embedded in the electronic page view 100.

Clicking via a mouse or other selection device, anywhere in the display area of the EIW 102, advances the selection of free-flowing text viewed by the user. Advancing the free-flowing text may also change the view or advance the electronic page view 100 to conform to what is being displayed in the EIW 102. When the user advances the selection of free-flowing text, a sequence of steps may be carried out. These include extracting new text from the electronic page view 100, placing the extracted text in the same or additional EIW 102, placing the extracted text at the top of a new column, and executing code sequence steps which relate to advancing the free-flowing text.

B. Information Manager

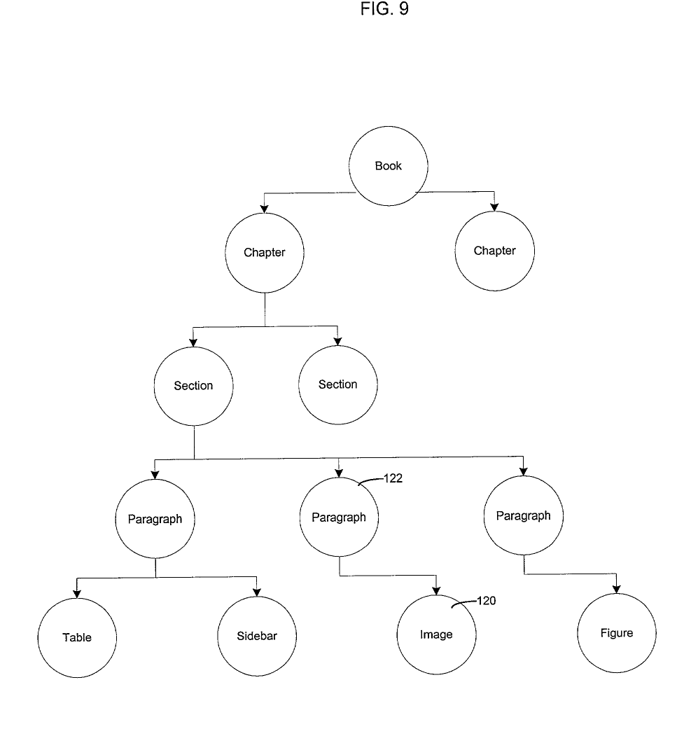

Among other functions, the information manager 104 functions to analyze, manage and send information from the electronic page view 100 to the EIW 102. As used herein, information includes markup annotations organized in a structure tree; text specifications, such as font, color and size, etc.; picture and multimedia resources; and page coordinate locations of these elements on the electronic page view 100. The information manager 104 serves the EIW 102 with extracted information to be viewed by the user. Information from the electronic document is saved in “markup data” and, thereby, the information manager 104 functions to manage markup data. Markup data includes markup annotations that delineate elements in the electronic document. The markup data also includes a structure tree that represents relationship information between structural elements in the electronic documents. Structural elements include a book, chapter, section, paragraph, table, figure, sidebar, image, audio, and visual files. In FIG. 9 a structure tree is shown which may be stored in the information manager. The structure tree may include the relationship that image 120 is a child element of paragraph 122.

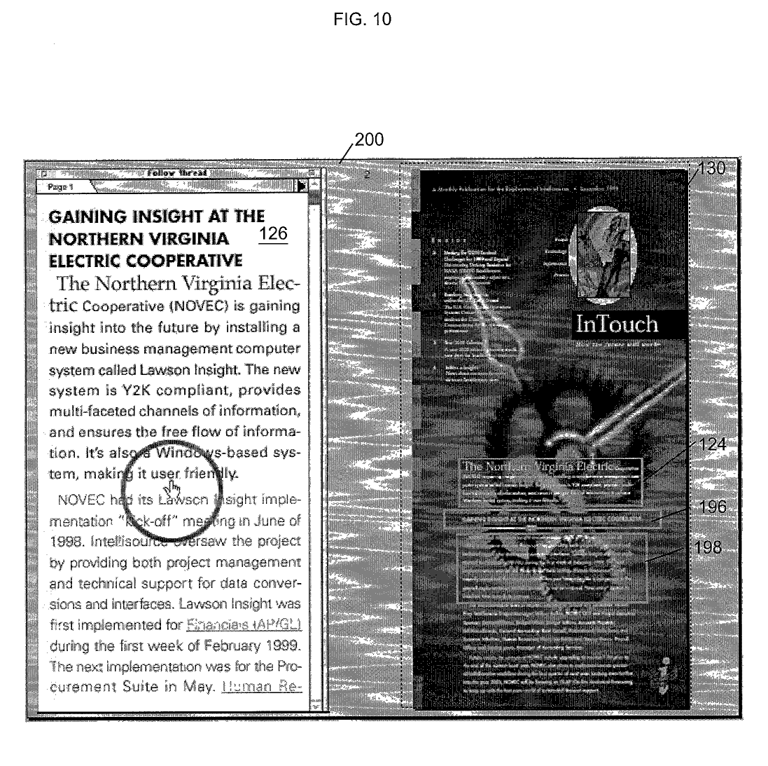

A markup author of the information manager 104 annotates portions of electronic page view 100 in the electronic document by adding markup annotations. Annotating is the process of defining coordinate parameters for portions of the electronic page view 100 in the electronic document and adding information related to the portion bounded by the coordinate parameters. For example, shown in FIG. 10 is an electronic document with markup annotations 124, 196, 198. Markup annotation 124 is defined by coordinate parameters and bounds textual information relating to “Northern Virginia Electronic Cooperative.” Three boxes have been drawn around three paragraphs on the electronic page view 130. The information manager extracts the information shown in the bounded boxes and displays it in the left display area 126 of the screen 200.

The markup data also includes information linking the markup annotations 124, 196, 198 with the extracted information in the display area 126. This linking information includes the location of the text which was extracted from the markup annotations 124, 196, 198 and the relationship of the markup annotations to other elements. By storing a markup annotation with structural element relationship information, such as illustrated in FIG. 9, the markup author of the information manager 104 manages the flow of information in the EIW 102.

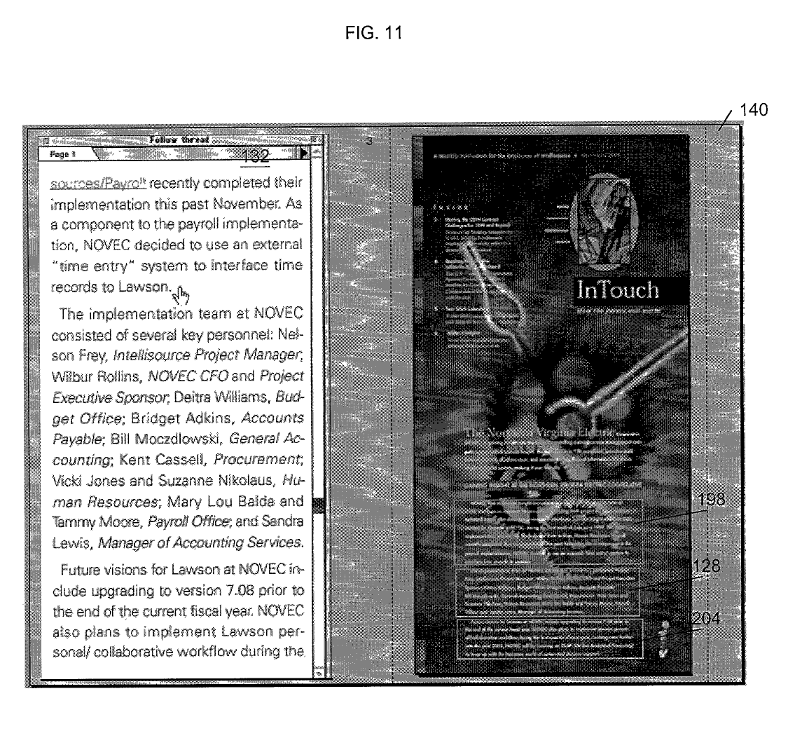

FIGS. 10 and 11 describe how the information manager works in practice. In FIG. 10, there is shown markup annotations 124, 196, 198 with the corresponding display area 126 and appropriate text information. The next markup annotations 128, 204 (shown in FIG. 11) contain paragraph elements that follow the paragraphs shown in annotations 124, 196, 198. When the computer user clicks (usually via mouse 110) on a markup annotation, the corresponding information is displayed in the left display area 126 of EIW 102. Further, when the user finishes comprehending the information in the display area 126, the user is given more information that follows the previously viewed information by clicking the mouse in display area 126 or by pressing a keyboard key, such as the Return key or Page down key. This new information flows as shown in the display area 132 and new markup annotations 128, 204 are highlighted in the electronic page view. By viewing the highlighted markup annotations on the electronic page view 100, the user is able to understand where on the electronic page view 100 he or she is reading. This embodiment of the EIW 102 preserves physical orientation features of a page without sacrificing readability of the textual information.

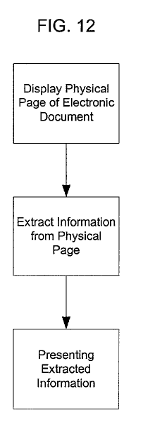

As shown in FIG. 12, a method for displaying and viewing electronic information includes the steps of (a) displaying in a first window an electronic page view from an electronic document where the electronic document includes representations of physical pages, (b) extracting information from the electronic page view, and (c) presenting the extracted information in a second window. The method may be used for uses such as electronic books and electronic coursebooks. For example, a computer user may have an electronic copy of a C programming book. Being able to see the electronic page view 100 in one window and being able to read portions of the electronic page view 100 in a second window may facilitate reading and comprehending of the electronic text. Alternatively, a user of PDAs or other handheld computers may want to carry a mystery novel in electronic form on a long-distance airplane trip. Such a user may want to know how many pages he or she has read or how many pages are left before he or she is finished with the book. Being able to view physical characteristics of a book in one window and read text in another window can enhance the electronic reading experience.

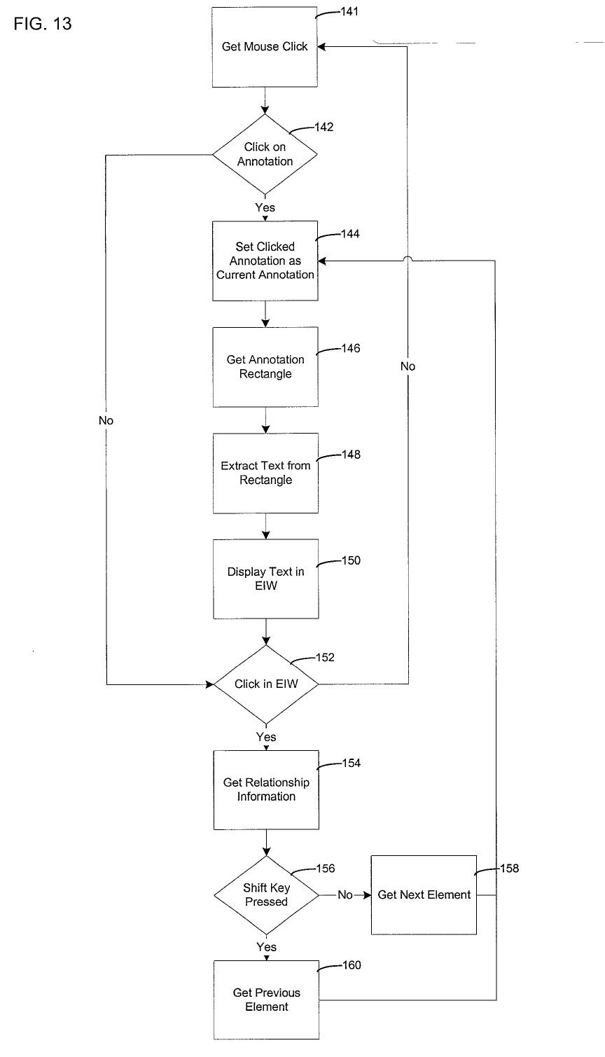

Specifically, as shown in FIG. 13, an embodiment of the method described above includes following markup annotations in a page description or document file format, such as PDF, to view an electronic page view, extract information from the electronic page view, and display the extracted information. In an embodiment of the invention, markup annotations may define textual, graphical or multimedia elements.

The step of displaying in a first window functions to present an electronic page view from a file in some page description or document file format, such as the PDF file format. A file may contain much electronic information representing many physical pages. The step of displaying an electronic page view may represent one physical page, multiple physical pages or a portion thereof from the file and display the graphic image in a window. The computer user may click on the displayed markup annotation (Block 142 in FIG. 13) whereby the annotation clicked on will be set as the current annotation (Block 144). Further, a rectangle bounding the text may be obtained for the markup annotation clicked on (Block 146) and its text extracted (Block 148). For example, in FIG. 10 electronic page view 130 represents a physical page and graphic 124 represents a markup annotation with a box around it. Extracting information from the text on an electronic page view bounded by a markup annotation may also be triggered by other events, such as clicking a bookmark, activating a hyperlink, voice command, or some other trigger that points to the structure tree at an associate markup annotation. Activating these other triggers takes the place of Blocks 141 and 142 in FIG. 13, where the annotation itself is not clicked, but the annotation which is associated with the trigger is set as the current annotation in block 144.

The step of extracting information functions to convert electronic information in a page (Block 148) to electronic information that may be manipulated for use by the EIW (Block 150). For example, in FIG. 11, portions of three paragraphs from electronic page view 140 have been selected for extraction. This step retrieves the information encompassed by markup annotations 198, 128 and 204 from the three paragraphs and translates the graphic into textual information as in the display area 132. Specifically, this step further requires seeking tags representing paragraph information and copying the text from the paragraph elements. and display the graphic image in a window. The computer user may click on the displayed markup annotation (Block 142 in FIG. 13) whereby the annotation clicked on will be set as the current annotation (Block 144). Further, a rectangle bounding the text may be obtained for the markup annotation clicked on (Block 146) and its text extracted (Block 148). For example, in FIG. 10 electronic page view 130 represents a physical page and graphic 124 represents a markup annotation with a box around it. Extracting information from the text on an electronic page view bounded by a markup annotation may also be triggered by other events, such as clicking a bookmark, activating a hyperlink, voice command, or some other trigger that points to the structure tree at an associate markup annotation. Activating these other triggers takes the place of Blocks 141 and 142 in FIG. 13, where the annotation itself is not clicked, but the annotation which is associated with the trigger is set as the current annotation in block 144.

The step of extracting information functions to convert electronic information in a page (Block 148) to electronic information that may be manipulated for use by the EIW (Block 150). For example, in FIG. 11, portions of three paragraphs from electronic page view 140 have been selected for extraction. This step retrieves the information encompassed by markup annotations 198, 128 and 204 from the three paragraphs and translates the graphic into textual information as in the display area 132. Specifically, this step further requires seeking tags representing paragraph information and copying the text from the paragraph elements.

The step of presenting the extracted information functions to give a computer user the ability to easily read the electronic information. As shown in FIG. 10, free flowing textual information is viewed in display area 126. Further, the user may easily comprehend the information in the electronic document by navigating the electronic page views by manipulating the display area 126. Specifically as shown in FIG. 10, the user may use the mouse to click in the display area 126 of the EIW 102 to advance in the structure tree to get further information (Blocks 152-160 in FIG. 13). For example, in FIG. 10, the user may click in column 126 to continue reading the text shown on the page (130 or 140) in FIGS. 10 and 11. As shown in FIGS. 10 and 11, clicking in the display area 126 of the EIW 102 advances the text and displays further information as in the display area 132.

Note the use of a mouse click is not meant to be limiting, but is by way of example. The computer user may use a variety of means to display, view and advance electronic information. These include a touchpad, stylus touch screen, a scroll wheel or button on a mouse like device such as a trackball, pen with a computer pad device, an eye motion sensor, an electromuscular current detector, keystroke, a combination of keys, and voice activated commands such as “more,” “next page,” “previous,” and “last page.”

The method may be carried out by general purpose computer systems, and/or specialized digital (or analog) logic systems. As an example of a programmed general purpose computer system implementation, the following program may use a programmed general purpose computer system, such as that based on an Intel PIII™ microprocessor based system. In this regard, the following C program implements a portion of the electronic information management system and illustrates the method for displaying and viewing electronic information of FIG. 12. C function “BSBReaderDoClick” extracts text from a part of a page bounded by an annotation and displays the text in the EIW 102, as shown in Blocks 142-150 of FIG. 13. C function “DisplayWindowMouseDown” finds annotations following from the ones currently displayed, extracts text from the part of the page bounded by the annotations, and displays the text in the EIW 102, as shown in Blocks 152-160 of FIG. 13. Further, in this embodiment, the C program makes use of the Adobe Acrobat Application Program Interface (API) to manipulate the PDF file and uses Tcl/Tk for displaying information in EIW 102.

/* This function is called when the user clicks on a markup annotatation.

This extracts text from the part of the page bounded by the annotation
and displays the text in the EIW. */

static ACCB1 ASBool ACCB2 BSBReaderDoClick(AVTool tool, AVPageView pageView,

ASInt16 xHit, ASInt16 yHit, ASInt16 flags, ASInt16 clickNo)

{

PDAnnot foundAnnot;
if (!AvPageViewIsAnnotAtPoint (pageView, xHit, yHit, &foundAnnot))

return false;

// We're on an annot. Is it a markup annot?
if (PDAnnotGetSubtype (foundAnnot) != BSBMarkup_K)
return false;
currentPageview = pageView;
currentAvDoc = AVPageViewGetAvDoc (currentPageView);
currentPDDoc = AVDocGetPDDoc (currentAvDoc);
if (displayWindowLocation == dispWinSide)

AVDocSetViewMode) currentAVDoc, PDUseBookmarks); //display bookmark pane

// Create word finder if it doesn't already exist for the PDDoc.
if (!wordFinder)

{
DURING
wordFinder = PDDocCreatewordFinder)currentPDDoc, NULL, NULL, NULL, 0,

WXE_XY_SORT, NULL);

HANDLER
char errorBuf [256];
AVAlertNote (“Error in creating word finder”);
AvAlertNote)ASGetErrorString (ASGetExceptionErrorCode(), errorBuf, 256));
END_HANDLER
}

KeepAnnot = DisplayNextBlock(foundAnnot);
return true;

} //BSBReaderDoClick

/* This function is called when the user clicks the mouse in the EIW. */
This code finds the next annotations after the ones currently displayed, extracts text from
the part of the page bounded by the annotations and displays the text in the EIW. */
int DisplayWindowMouseDown)ClientData clientData, Tcl_Interp *interp, int argc, char (argv[])

{
float first, last;
PDAnnot prevAnnot;
_ElementPart elementPart;

// Scroll screen. If shift key pressed, scroll up.
if (AvSysGetModifiers() & AV_SHIFT)
// Scroll up one screen. If at top, move to previous rectangle.
// Shift key pressed.
/* Have we already scrolled up all the way to the top?
{
char command2[] = “.textWindow yview”;
retcode = Tol_Eval(tclInterp, command2);
sscanf(tclInterp−>result, “%f %f”, &first, &last);
// If at top, move to previous text block.
if (first == 0.0)

{
// Go back to beginning of previous text block.
prevAnnot = firstAnnotinWindow;
for (ASInt32 i = 1; i <= NUMBERPARAGRAPHSPERBLOCK; i++)

{
// Go back to start of whole element.
do

{
prevAnnot = MUAnnotGetPrev(prevAnnot);
elementPart = MUAnnotGetElementPart (prevAnnot);
}

while ((elementPart != wholeElementPart) && (elementPart != beginElementPart));

}
nextAnnot = DisplayNextBlock(prevAnnot);
char command2[] = “.textWindow yview scroll 100 pages”; //scroll to bottom
retcode = Tcl_Eval)tclInterp, command2);
}

else
// Scroll up one screen.

{
char command1[] = “.textWindow yview scroll −1 pages”;
retcode = Tcl_Eval(tclInterp, command1);
}

}

else

// Shift key not pressed.
{
/* Have we already scrolled down all the way to the bottom?
char command2[] = “.textwindow yview”;
retcode = Tcl_Eval(tclInterp, command2);
sscanf(tclInterp−>result, “%f %f”, &first, &last);
// If at end, move to next text block.
if (last == 1.0)

nextAnnot = DisplayNextBlock(nextAnnot);

else
// Scroll down one screen.

{
char command[] = “.textWindow yview scroll 1 pages”;
retcode = Tcl_Eval(tclInterp, command1);
}

}

tclInterp−>result = “”;
return TCL_OK;

} //DisplayWindowMouseDowm

The present invention may be embodied in the form of computer-implemented processes and apparatuses for practicing those processes. The present invention can also be embodied in the form of computer program code embodied in tangible media, such as floppy diskettes, CD-ROMs, hard drives, or any other computer-readable storage medium, wherein, when the computer program code is loaded into and executed by a computer, the computer becomes an apparatus for practicing the invention. The present invention can also be embodied in the form of computer program code, for example, whether stored in a storage medium, loaded into and/or executed by a computer, or transmitted over some transmission medium, such as over electrical wiring or cabling, through fiber optics, or via electromagnetic radiation, wherein, when the computer program code is loaded into and executed by a computer, the computer becomes an apparatus for practicing the invention. When implemented on a general-purpose microprocessor, the computer program code segments configure the microprocessor to create specific logic circuits.

C. Tools

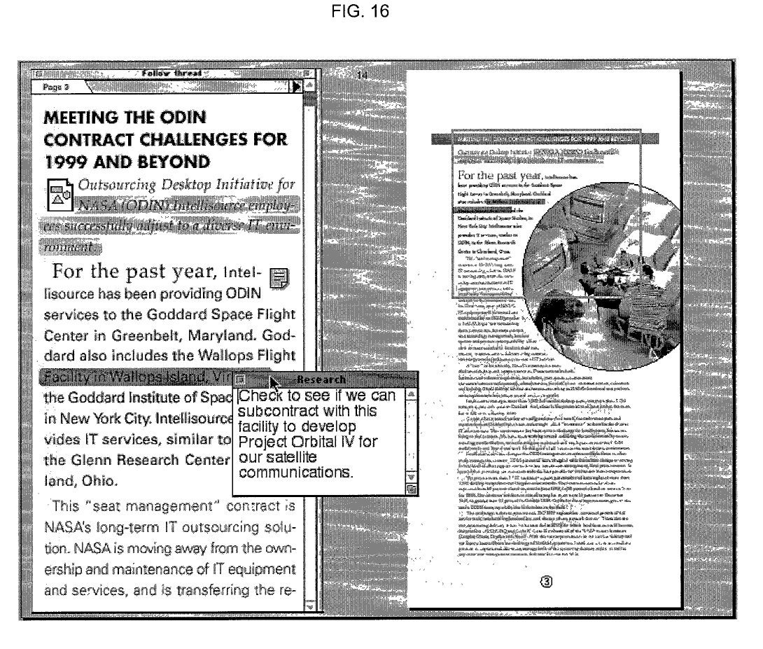

An embodiment of the present invention allows the user to add notes to an electronic document. As a user is reading an electronic text relating to NASA as shown in FIG. 16, the user may want to remark that the information requires further research. Shown in FIG. 16 is an example of a note added to a document. The text is highlighted to visually call attention to the reader and may have further information available in the form of a note. Further, clicking the mouse or otherwise selecting the text that is associated with the note displays the note to the user. Notes can be in the form of typed text, handwritten notes with stylus or a combination of the two using handwriting recognition functions. Other user created annotations may also append files in the form of word processing files, encapsulated postscript files and PDF files. Still other user created annotations may be a bookmark tool to tag spots in the EIW 102, voice recordings and voice to text recognition, a notepad with word processing capabilities, or a tool to add user defined hyperlinks within the EIW to other structural elements.

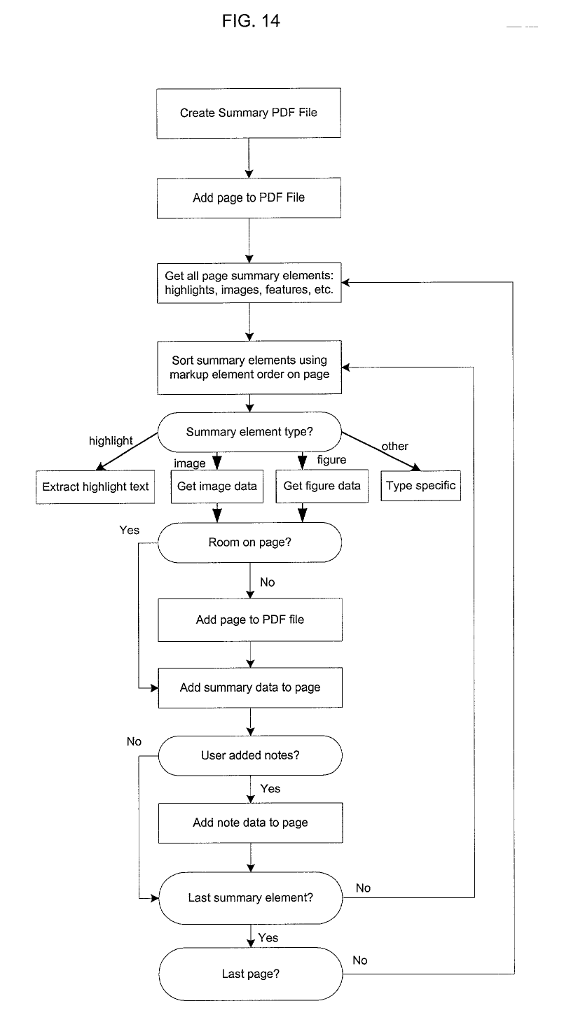

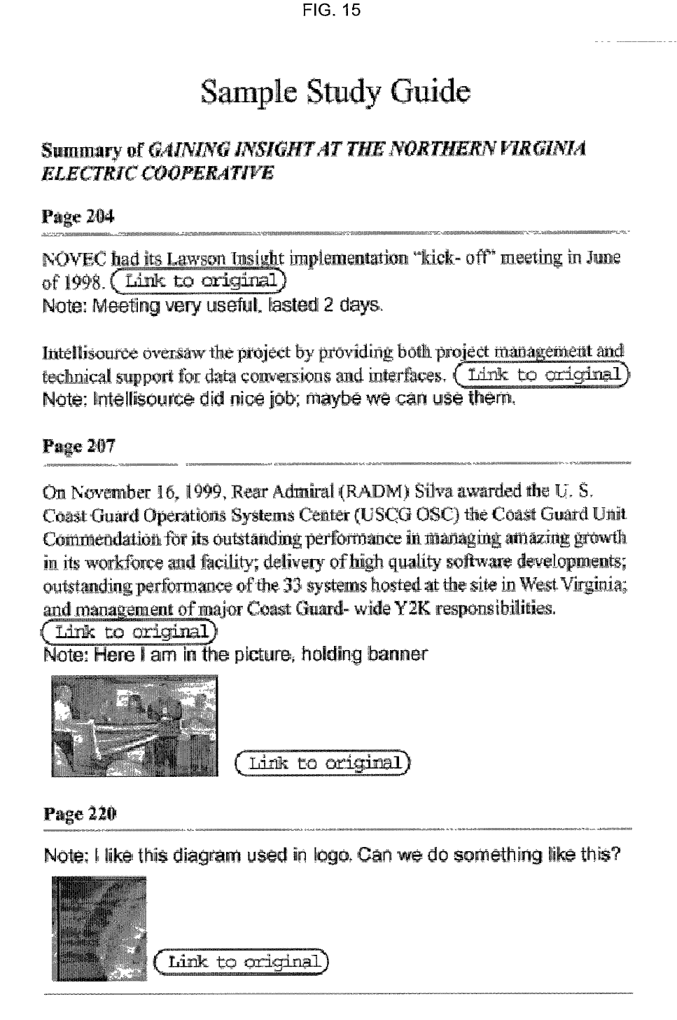

From the notes added to the electronic document, the user can create a personal study guide from the information shown in EIW 102. FIG. 14 shows a flow diagram for creating a study guide. The user is able to create a study guide which includes electronic information from the EIW 102 including text, images, and figures. An example study guide is shown in FIG. 15.

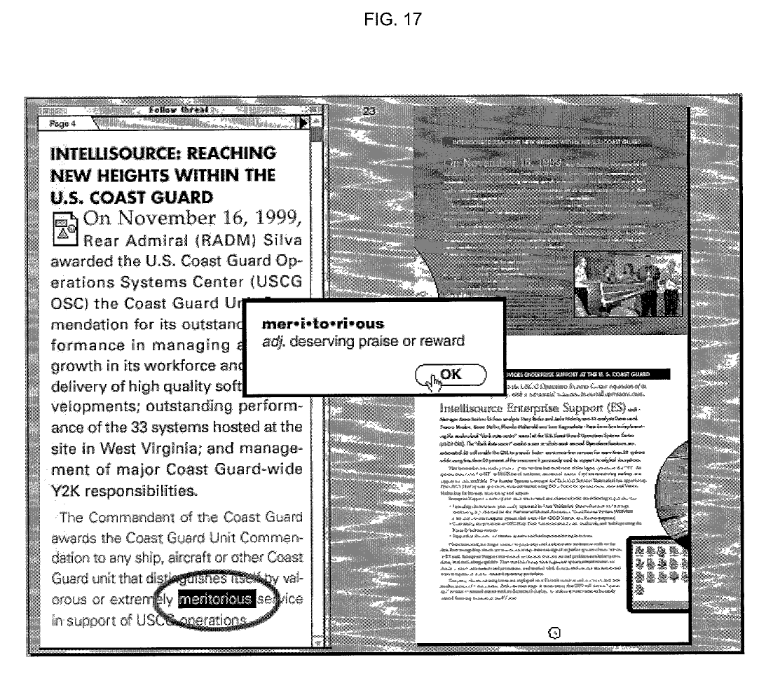

An embodiment of the present invention allows the user to look-up unfamiliar words in a dictionary. For example, the user may be unfamiliar with the word “meritorious”. Clicking on the word and selecting a dictionary may display a definition for the word. In another embodiment, clicking on the word also presents a pronunciation of the word. Shown in FIG. 17 is a screen shot of how this tool works. The dictionary used may be a built-in dictionary, local files on the user's computer, or an Internet-based dictionary. Further, the user may specify to retrieve a definition of an unfamiliar word using a search engine on the Internet. For example, computer terms that may not be in the built in dictionary, may be found on a specialized database for technical terms, such as Webopedia by Internet.com. An embodiment of the present invention may allow the user to select the location where a definition may be retrieved. Further, if after retrieving a definition for an unfamiliar term, the computer user may be prompted to learn more information by listening to a lecture or viewing class notes relating to the unfamiliar term.

An embodiment of the present invention allows the user to look-up unfamiliar words in an encyclopedia. For example, the user may be unfamiliar with the term “appendectomy”. Clicking on the word and selecting an encyclopedia may display the required information to understand the term. The encyclopedia used may be a built-in encyclopedia, local encyclopedia on the user's computer, or an Internet-based encyclopedia. Further, the user may wish to retrieve a lecture or view an appendectomy surgery by connecting with a remote computer, such as via the Internet. An embodiment of the present invention may allow the user to select the location where information may be sought.

III. Synchronization, Compatibility, and Enhancements

An illustrative embodiment of the system incorporates extensive synchronization features, wherein synchronization is defined as sharing information between more than one computer. For example, one embodiment of the system resides on a desktop computer. With such an embodiment of the system, the user is able to synchronize information between the desktop and a third party information management system residing on a PDA, other handheld computer, or a laptop computer. In such an embodiment, the computer user may synchronize an electronic document on the desktop with one on a PDA or a laptop computer. Alternative embodiments may reside completely on their own in a PDA or a laptop computer.

An exemplary embodiment of the system may also provide World Wide Web services. In such an embodiment, the system consists of an off site Web server to which users can upload electronic documents. Such a Web server further may offer global access to electronic documents that do not exist on the computer user's local computer system. Users can then access, organize, and navigate a Web representation of the uploaded information. Furthermore, such an embodiment would provide synchronization services between the Web server and the computer user's local computer system. The Web server may also provide sharing services to enable a second user to access the computer user's electronic documents in accordance with the first user's permission. For example, a computer user named Mark may want to share his electronic copy of XYZ book with computer users Carole and Scott. Mark may set a time limit for when users Carole and Scott may access his book and for how long they may keep the book. Thus, the Web server may serve as a manager of “loaned” electronic documents.

IV. Portability

The present invention is portable via diskettes, e-mail, LAN/WAN connection or over the Internet via upload and download to any computer. In an exemplary embodiment, the computer user's electronic documents may be transferred to another computer. For example, this enables the user to carry his electronic books from one computer to any other computer.

The present invention can also be installed on a network server. This would allow the user to maintain his electronic documents he or she moves from one workstation to another. In a preferred embodiment, the user's electronic documents are made secure via a password.

Portability will now be explained by way of example. Suppose computer user, Gary, decides to travel for a brief work assignment. Gary creates a series of diskettes that will contain an electronic document. Alternatively, Gary could transfer his electronic document to a web site so that he could then transfer the electronic document into his computer at the other office as soon as he arrives there. Further, Gary may want to carry his electronic document with him as he travels and he may want to download it to his PDA.

V. Advanced Features

In an alternative embodiment, an embodiment of the present invention may employ algorithms that can analyze a query styled in natural language and be able to respond to that query. Natural language is defined as a way of wording something that emulates how we speak. Algorithms can account for various languages with varying dialects. In this way, an end user is not required to memorize cryptic commands to get the software to answer simple queries. Queries can be input through various means, such as keyboard and the spoken word.

In an alternative embodiment, an embodiment of the present invention may employ filtering processes to present in the EIW things that are user defined as desirable, leaving out the remaining content. An example of this may be termed as a “skim mode”, where only the heads/subheads and the first lines of paragraphs are presented. Other variations include presenting pertinent information to a query made by the user or presenting information on related topics. The filtering process may work in several ways, graying out the unwanted text, highlighting the desired text or removing the unwanted text altogether from the display area of the EIW.

While the present invention has been described with respect to various specific embodiments and examples, it will be appreciated that a wide variety of modifications, adaptations and derivations may be made which are within the spirit and scope of the present invention as defined by the following claims and equivalents thereof.

What is claimed is:

1. A method for viewing electronic information comprising the steps of:
displaying in a first window a physical page from an electronic document containing information from a predefined page format, wherein the electronic document comprises representations of at least one physical page, and a visual reference emphasizing information on the at least one physical page,
extracting the information emphasized by the visual reference on the at least one physical page, and
presenting the extracted information in a second window.

2. The method of claim 1 wherein the physical page is represented in an electronic page view.

3. The method of claim 1 wherein the physical page is represented as an icon including a thumbnail of the physical page.

4. The method of claim 1 wherein the first and second window are the same window.

5. The method of claim 1 wherein the second window is an enhanced interactive window including a thumbnail image of a physical page, a graphic image of a physical page, text, free flowing text, icons, hyperlinks, menus, and control elements.

6. The method of claim 1 wherein the step of extracting information further comprises the step of selecting a markup annotation from the physical page and converting the information contained in the selected markup annotation to information for use in the second window.

7. The method of claim 6 wherein the step of selecting further comprises the step of enclosing the markup annotation with a box.

8. The method of claim 1 wherein the second window may be placed in various positions relative to the first window, including on top of the first window, adjacent to the first window, and partially covering the first window.

9. The method of claim 1 wherein the second window further comprises a control panel for managing the extracted information.

10. The method of claim 1 wherein the extracted information may be viewed simultaneously in a multiple of enhanced interactive windows.

11. The method of claim 1 wherein the visual reference on the physical page is a box with a colored border.

12. The method of claim 1 wherein the step of extracting information further comprises the step of extracting information when a computer user clicks in the first window by a selection device including a mouse and the information which is extracted is around the point of the mouse click.

13. The method of claim 1 wherein the step of extracting information further comprises the step of selecting a bookmark and retrieving information associated with the bookmark.

14. The method of claim 1 wherein the step of extracting information further comprises the step of retrieving information associated with a structural element when the user selects the structural element

15. The method of claim 1 wherein the information emphasized by a visual reference is termed a markup annotation and each markup annotation is associated with a structural element stored in a database of structural elements.

16. The method of claim 1 wherein the step of presenting extracted information further comprises the step of retrieving an associated structural element from a database of structural elements and displaying data from the markup annotations associated with the structural elements in the second window.

17. The method of claim 1 wherein the step of presenting extracted information further comprises the step of enlarging and reducing visual elements in the first window.

18. The method of claim 17 wherein the visual elements include graphic images, clip art, and picture objects.

19. The method of claim 1 wherein the step of presenting extracted information further comprises the step of emphasizing hyperlinks by representing the hyperlinks as hypertext.

20. The method of claim 19 wherein the hyperlinks are associated with visual elements.

21. The method of claim 1 further comprising the steps of:
selecting a symbol representing extracted information in the second window, and
displaying document elements associated with the symbol in the first window.

22. The method of claim 21 wherein the symbol includes graphical icons for tables, textual icons for tables, figures, graphs, charts, illustration graphics, photos, clip art, audio elements, audiovisual elements, and hyperlink messages.

23. The method of claim 21 wherein selecting a symbol further comprises the step of enlarging or reducing a zoom view of the extracted information in the first window.

24. The method of claim 21 wherein selecting a symbol displays the extracted information in a third window.

25. The method of claim 21 wherein selecting a symbol displays text in another enhanced interactive window.

26. The method of claim 21 wherein selecting a symbol executes a code sequence relating to the symbol.

27. The method of claim 21 wherein document elements include information comprising tables, figures, graphs, charts, illustration graphics, photos, clip art audio and audiovisual elements.

28. The method of claim 21 wherein the step of selecting includes clicking on the symbols with a mouse.

29. The method of claim 21 wherein the third window is an enhanced interactive window including a thumbnail image of a physical page, a graphic image of a physical page, text, free flowing text, icons, hyperlinks, menus, and control elements.

30. The method of claim 21 wherein the third window may be placed in various positions relative to the first and second windows, including on top of the other windows, adjacent to the other windows, and partially covering the other windows.

31. The method of claim 1 wherein the step of displaying extracted information further comprises the step of advancing extracted information in the second window by clicking in the second window in areas not designated by symbols, icons, hyperlinks or hypertext.

32. The method of claim 1 wherein the step of displaying extracted information further comprises the step of advancing extracted information in the second window by an action including a keystroke, keystroke combinations, scroll wheels and voice commands.

33. The method of claim 32 wherein the step of advancing extracted information in the second window further comprises the step of advancing the physical page displayed in the first window.

34. The method of claim 32 wherein the step of advancing extracted information in the second window further comprises the step of advancing the visual reference to the extracted information in the physical page displayed in the first window.

35. The method of claim 1 wherein the extracted information will start at the top of the second window.

36. The method of claim 1 further comprising the step of creating a summary document from user created notes, highlights, and other user inputted information.

37. The method of claim 1 wherein the step of presenting extracted information further comprises the step of allowing the user to add to the extracted information in the second window.

38. The method of claim 1 wherein the step of presenting extracted information further comprises the step of finding words within the second window.

39. The method of claim 1 further comprising the step of presenting a dictionary to a user to retrieve definitions for unfamiliar words.

40. The method of claim 1 further comprising the step of presenting an information database to a user to retrieve definitions for unfamiliar words.

41. The method of claim 1 further comprising the step of examining extracted information for unfamiliar words and displaying definitions for the unfamiliar words.

42. The method of claim 1 wherein the electronic information is associated with a particular computer.

43. The method of claim 1 wherein the electronic information may be shared between computer users and between computers.

44. A system for viewing electronic information comprising:
means for displaying in a first window a physical page from an electronic document, wherein the electronic document comprises representations of at least one physical page, and a visual reference emphasizing information on the at least one physical page,
means for extracting the information emphasized by the visual reference on the at least one physical page, and
means for presenting the extracted information in a second window.

45. The system of claim 44 further comprising
means for selecting extracted information represented by symbols in the second window, and
means for displaying document elements associated with the symbols in a third window.

46. A computer system for viewing electronic information, the electronic information comprising textual and graphic data of electronic books and documents, the system comprising:
an information manager for manipulating graphic images of physical pages and annotations bounding electronic information from the physical pages,
an enhanced interactive window for displaying the electronic information, and
at least one tool for manipulating the electronic information in the enhanced interactive window.

47. The system of claim 46 wherein the enhanced interactive window comprises at least one window that displays extracted information from the physical pages.

48 The system of claim 46 wherein the enhanced interactive window includes a thumbnail image of a physical page, a graphic image of a physical page, text, free flowing text, icons, hyperlinks, menus, and control elements.

49. The system of claim 46 wherein the information manager further comprises a database for storing annotations, extracted electronic information, and the relationships in the system.

50. The system of claim 46 wherein the database includes a structure tree for storing relationship information associating electronic information with extracted electronic information.

51 The system of claim 46 wherein a visual reference emphasizing the electronic information is displayed on the physical pages.

52. The system of claim 51 wherein the visual reference is a box with a colored border.

53. The system of claim 46 further comprising a dictionary to allow a user to retrieve definitions for unfamiliar words.

54. The system of claim 46 further comprising a lock which allows the electronic information to be associated with one computer.

55. The system of claim 46 further comprising a sharing mechanism which allows a computer user to share electronic information between computer users and between computers.

56. The system of claim 46 wherein the graphic images of physical pages adhere to a page description format.

57. A computer system for viewing electronic information, the system comprising:
a visual display for displaying an enhanced interactive window based upon electronic information in a page description format;
a storage medium for storing and retrieving information related to the electronic information in the page description format;
a computer processor coupled to the visual display and to the storage medium for accessing and processing information stored in the storage medium to provide a display of the enhanced interactive window;
an input means coupled to the computer processor for entering information related to the electronic information in the page description format;
a software portion for creating a plurality of relationships between the enhanced interactive window and the electronic information in the page description format; and
a software portion for providing a graphical user interface for navigation and display.

58. The system of claim 57 wherein the enhanced interactive window comprises
a software portion for displaying electronic information in a page description format in a first window;
a software portion for displaying electronic information extracted from the page description format in a second window, whereby a visual reference emphasizing the extracted electronic information is displayed in the first window;
a software portion for traversing through related electronic information, whereby selection of electronic information in the first window advances the extracted electronic information displayed in the second window until the desired information is ultimately displayed; and
a software portion for traversing through related electronic information, whereby selection of extracted electronic information in the second window advances the extracted electronic information displayed in the second window until the desired information is ultimately displayed.
